(19) United States
(12) Patent Application Publication
(10) Pub. No.: US 2026/0182370 A1
(43) Pub. Date: Jun. 25, 2026

(54) LEVELING CONTROL FOR SEMICONDUCTOR DEVICE PACKAGE ATTACHMENT

(71) Applicant: SEMICONDUCTOR COMPONENTS INDUSTRIES, LLC, Scottsdale, AZ (US)

(72) Inventors: Seungwon IM, Bucheon (KR); Jonghwan BAEK, Gimpo-city (KR); Dongwook KANG, Bucheon (KR)

(73) Assignee: SEMICONDUCTOR COMPONENTS INDUSTRIES, LLC, Scottsdale, AZ (US)

(21) Appl. No.: 18/987,146

(22) Filed: Dec. 19, 2024

(51) Int. Cl. H01L 23/373; H01L 21/48; H01L 21/67; H01L 23/367

(52) U.S. Cl. CPC H10W 40/255; H10P 72/0438; H10W 40/037; H10W 40/22

(57) ABSTRACT

In a general aspect, a semiconductor device assembly includes a heat dissipation device, and a semiconductor device package having a primary surface defined by an encapsulant material and a metal layer exposed through the encapsulant material. The assembly further includes a conductive adhesive coupling the metal layer of the primary surface with a first portion of the heat dissipation device. The assembly also includes a spacer material disposed between the encapsulant material of the primary surface and a second portion of the heat dissipation device.

### BACKGROUND

Semiconductor device assemblies can include semiconductor device packages and heat dissipation devices (e.g., cooling jackets, heat sinks, etc.). In prior implementations, tilting of a semiconductor device package, e.g., relative to a corresponding heat dissipation device, can occur during attachment of the package to a corresponding heat dissipation device. Such tilting can result in voids in an attachment adhesive and/or delamination of the package from the heat dissipation device, e.g., due to poor adhesion resulting from package tilting. Such voids and/or delamination can reduce operational performance and/or cause reliability issues due to adverse effects of voids and/or delamination on thermal dissipation efficiency during operation of one or more semiconductor devices included in the semiconductor device package.

### SUMMARY

In a general aspect, a semiconductor device assembly includes a heat dissipation device, and a semiconductor device package having a primary surface defined by an encapsulant material and a metal layer exposed through the encapsulant material. The assembly further includes a conductive adhesive coupling the metal layer of the primary surface with a first portion of the heat dissipation device. The assembly also includes a spacer material disposed between the encapsulant material of the primary surface and a second portion of the heat dissipation device.

In another general aspect, a method for producing a semiconductor device assembly includes depositing a sintering material on a first portion of a heat dissipation device, and depositing a spacer material on a second portion of the heat dissipation device. The method also includes placing a first surface of a semiconductor device package on the sintering material and the spacer material such that a metal layer of the first surface is disposed on the sintering material and an encapsulation material of the first surface is disposed on the spacer material. The method further includes applying pressure to a second surface of the semiconductor device package with a sintering tool, where the second surface is opposite the first surface. The method further includes applying heat to the semiconductor device assembly to sinter the metal layer to the heat dissipation device with the sintering material.

In another general aspect, a method for producing a semiconductor device assembly includes depositing a sintering material on a metal layer included in a first surface of a semiconductor device package, and placing the semiconductor device package on a heat dissipation device such that the sintering material is in contact with a first surface of the heat dissipation device. The method further includes positioning a second surface of the heat dissipation device in contact with a first sintering tool using a first motor-operated level controller, where the second surface of the heat dissipation device is opposite the first surface of the heat dissipation device. The method also includes applying pressure to a second surface of the semiconductor device package with a second sintering tool using a second motor-operated level controller. The second surface of the semiconductor device package is opposite the first surface of the semiconductor device package. The method also includes applying heat to the semiconductor device assembly to sinter the metal layer to the heat dissipation device with the sintering material.

In another general aspect, an apparatus for producing a semiconductor device assembly includes: a first sintering tool that has a fixed position. The apparatus also includes a first motor-operated level controller configured to position a heat dissipation device in contact with the first sintering tool. The apparatus further includes a second sintering tool, and a second motor-operated level controller configured to apply pressure to a semiconductor device package with the second sintering tool during a sintering operation to sinter the semiconductor device package to the heat dissipation device.

### BRIEF DESCRIPTION OF THE DRAWINGS

FIG. 1A is a diagram illustrating an example heat dissipation device (cooling jacket) that can be included in a semiconductor device assembly.

FIG. 1B is a diagram illustrating the example heat dissipation device of FIG. 1A with spacer material disposed on the cooling jacket.

FIG. 2 is a diagram illustrating an example semiconductor device assembly.

FIG. 3 is a diagram schematically illustrating a cross-sectional view of an example semiconductor device assembly.

FIG. 4 is a diagram schematically illustrating a cross-sectional view of another example semiconductor device assembly.

FIG. 5 is a diagram schematically illustrating an example approach for sintering a semiconductor device package with a heat dissipation device using position and leveling control apparatus.

FIG. 6 is a diagram schematically illustrating an example approach for sintering a semiconductor device package with a heat dissipation device using a spacer material for leveling control.

FIG. 7 is a flowchart illustrating an example method for producing a semiconductor device assembly, which can be implemented using the approach of FIG. 5.

FIG. 8 is a flowchart illustrating an example method for producing a semiconductor device assembly, which can be implemented using the approach of FIG. 6.

In the drawings, which are not necessarily drawn to scale, like reference symbols may indicate like and/or similar components (elements, structures, etc.) in different views. The drawings illustrate generally, by way of example, but not by way of limitation, various implementations discussed in the present disclosure. Reference symbols shown in one drawing may not be repeated for the same, and/or similar elements in related views. Reference symbols that are repeated in multiple drawings may not be specifically discussed with respect to each of those drawings, but are provided for context between related views. Also, not all like elements in the drawings are specifically referenced with a reference symbol when multiple instances of an element are illustrated.

### DETAILED DESCRIPTION

This disclosure relates to implementations of electronic device assemblies, e.g., semiconductor device assemblies that include one or more semiconductor devices packages coupled with (attached to, mounted on, etc.) a heat dissipation device, such as a heat sink, cooling jacket, etc. For instance, in some implementations one or more semiconductor device packages can be coupled with a heat sink. In some implementations, one or more semiconductor device packages can be coupled with a cooling jacket (cooling pipe, water jacket, etc.) In some implementations, other arrangements of semiconductor device packages and corresponding heat dissipation devices are possible.

Such semiconductor assemblies can be used in high-power applications, such as automotive and/or industrial applications. For instance, the implementations described herein can be included in high-power applications, such as power converters, traction inverter systems, ignition circuits, etc.

As power requirements for such semiconductor device assemblies increase, semiconductor materials that support higher power densities are being used to implement power semiconductor devices for use in such assemblies. As one example, field-effect transistors (FETs) implemented in silicon carbide can be used in place of insulated-gate bipolar transistors implemented in silicon. This can facilitate achieving equivalent, or even higher power ratings for transistors implemented on smaller semiconductor die, e.g., semiconductor die with smaller areas. In some implementations, such smaller semiconductor die can allow for achieving cost savings by reducing a size of a corresponding substrate on which the semiconductor die are disposed in a semiconductor device package, such as a molded semiconductor device power module or package.

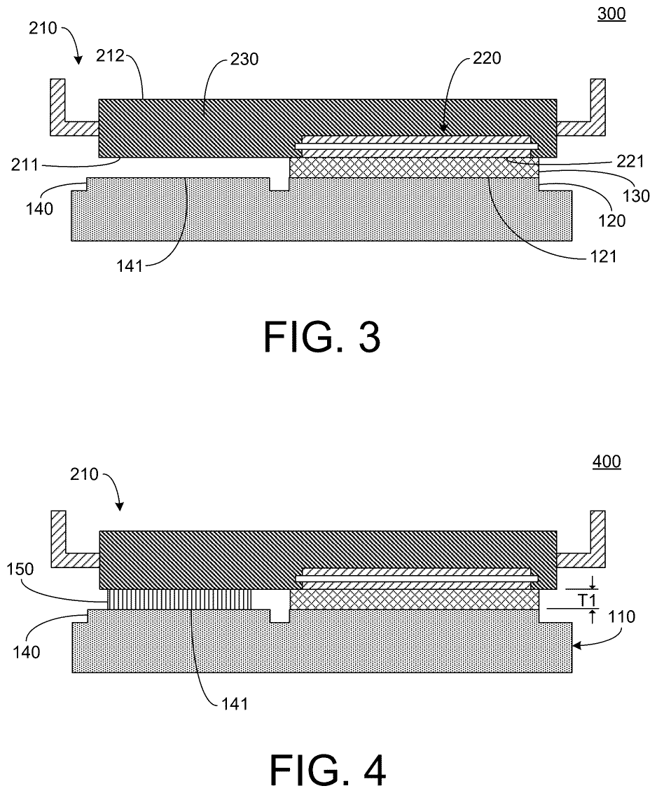

In some implementations, a substrate can be a direct-bonded metal (DBM) substrate, e.g. a direct-bonded copper (DBC) substrate. A DBM substrate can include an insulator layer (e.g., a ceramic layer), a first conductive layer, such as a first metal layer (e.g., a patterned metal layer including a conductive member and electrically conductive traces) disposed on a first side of the insulator layer. A DBM substrate can also include a second conductive layer, such as a second metal layer (e.g., for attachment to a heat dissipation device) disposed on an opposite side of the insulator layer. In some implementations, such as DBC implementations, the first metal (conductive) layer and the second metal (conductive) layer are copper layers. Example implementations including a DBM substrate are schematically shown in FIGS. 3-6. In some implementations, a die attach paddle of a leadframe can be used instead of, or in place of a DBM substrate.

In some implementations, such as automotive applications, maintaining a consistent form factor is desired. Maintaining a constant form factor can include implementing semiconductor device assemblies with semiconductor device packages and corresponding heat dissipation devices that have specific dimensions. In order to facilitate direct cooling, a metal layer of a substrate can be exposed through a molding compound of a semiconductor device package. For instance, a primary surface of a semiconductor device package can include (be defined by) an exposed metal layer of a substrate and a molding compound surface. Reducing a substrate size included in a semiconductor device package of a given form factor will result in a change (e.g., a reduction) in a ratio of a portion of a primary surface defined by the exposed metal layer relative to a portion of the primary surface defined by the molding compound. A technical problem that can occur in such implementations is package tilt. For instance, such package tilt can occur when attaching a semiconductor device package to a heat dissipation device, e.g., due,, at least in part, to the reduced area of the metal layer of being attached to the heat dissipation device relative to the increased area of the molding compound. That is, package tilt can occur as a result of shifting of a position of a semiconductor device package during attachment, e.g., sintering, of the metal layer to a corresponding heat dissipation device. Such package tilt can adversely affect thermal dissipation efficiency during operation of the resulting semiconductor device assembly due to voids in a conductive attachment adhesive and/or delamination of the semiconductor device package from the heat dissipation device.

One technical solution to the foregoing technical problem is use of position and leveling control during attachment of a semiconductor device package or multiple semiconductor device packages to a corresponding heat dissipation device. For instance, one or more motor-operated (e.g., servo motor, stepper motor, etc.) controlled level controllers can be used to maintain respective positions of the semiconductor device package(s) and the heat dissipation device relative to one another during attachment of the package(s) to the corresponding heat dissipation device. Another technical solution to the foregoing technical problem is to use a spacer material (gap filler material, gap adjust material, etc.) in addition to a conductive adhesive (e.g., sintering material, etc.) when attaching one more semiconductor device packages to a corresponding heat dissipation device. For instance, the gap filler material can be of a same thickness as the conductive adhesive material and be disposed between molding compound of a primary surfaces of a semiconductor device package and the heat dissipation device, while the conductive adhesive material is disposed between a metal layer of the primary surface and the heat dissipation device. A technical benefit of the foregoing technical solutions is reduction or prevention of package tilt and associated voids in the conductive adhesive material and/or delamination of the semiconductor device package from the heat dissipation device, which can improve thermal dissipation efficiency.

As used herein, the primary surface of a semiconductor device package refers to an exterior surface of a package having a larger surface area than one or more other exterior surfaces of the package, e.g., a largest surface area. In some implementations, a semiconductor device package can have a first primary surface and a second primary surface, where the second primary surface is on an opposite side of the semiconductor device package. In some implementations, a first primary surface and a second primary surface can have a same surface area. In some implementations, a first primary surface and a second primary surface can have different surface areas, which are both larger than respective surface areas of other surfaces of a semiconductor device package. In some implementations, a primary surface is arranged in (e.g., aligned with) a plane that is parallel with a plane of a semiconductor die included in the package.

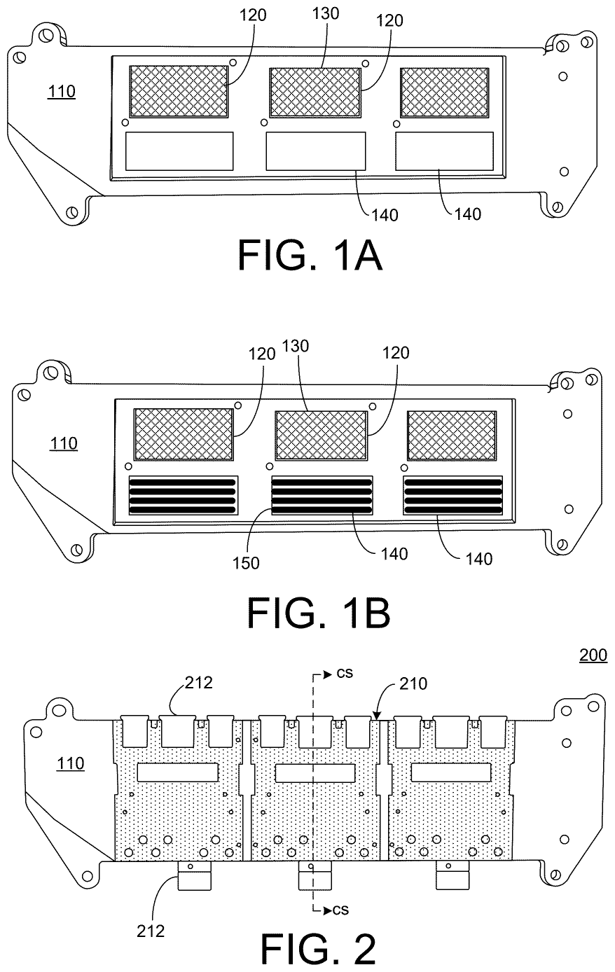

FIG. 1A is a diagram illustrating an example heat dissipation device 110 that can be included in a semiconductor device assembly. In the example of FIG. 1A, the heat dissipation device 110 is illustrated as a cooling jacket or water jacket. In some implementations, the heat dissipation device 110 can be a heat sink or other heat dissipation device. As shown in FIG. 1A, the heat dissipation device 110 includes a plurality of raised portions 120. In this example, the raised portions 120 can be coupled to metal layers of semiconductor device packages to facilitate direct cooling for those packages. The raised portions 120, respectively, have a conductive adhesive 130 disposed on their upper surfaces. In some implementations, the conductive adhesive 130 can be a sintering material, such as a silver sintering material or a copper sintering material. For instance, the sintering material can be a sintering material paste that is printed on the upper surfaces of the raised portions 120.

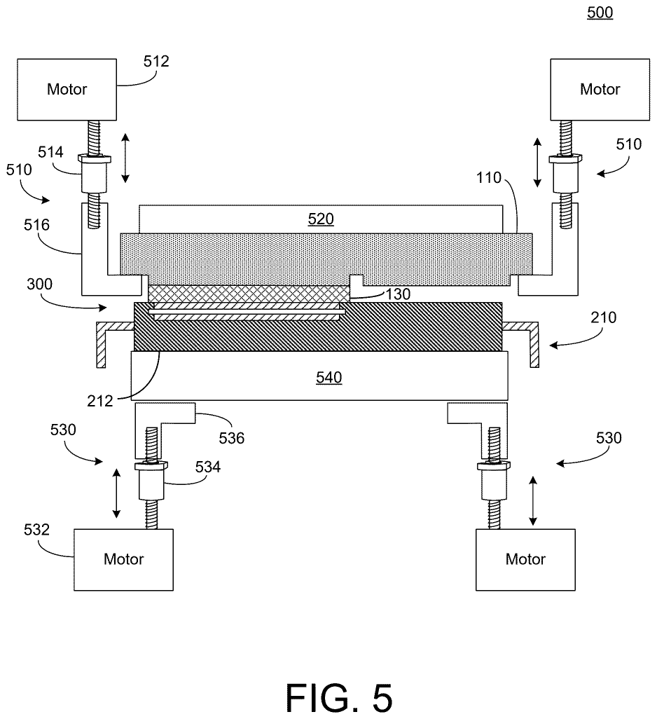

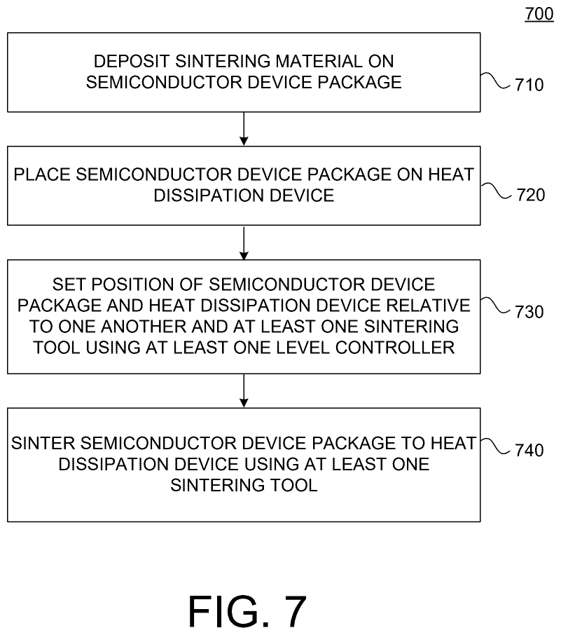

As shown in FIG. 1A, the heat dissipation device 110 also includes a plurality of raised portions 140, which have respective upper surfaces that are coplanar with the upper surfaces of the raised portions 120, and are also discontinuous with the raised portions 120. For instance, a groove or grooves (channels, etc.) can be disposed between the raised portions 120 and the raised portions 140. Such an arrangement can prevent outflow of the conductive adhesive 130 from contacting portions of a corresponding semiconductor device package that are outside the perimeter of an exposed metal layer included in a primary surface of the package, e.g., contacting portions of the primary surface including molding compound. In some implementations, the heat dissipation device 110, as illustrated in FIG. 1A, can be used to produce a semiconductor device assembly using one or more position and level controllers to reduce and/or prevent package tilt during attachment (e.g., sintering), e.g., to produce the example assembly shown in FIG. 3 using the approach shown in FIG. 5, and/or in accordance with the method of FIG. 7.

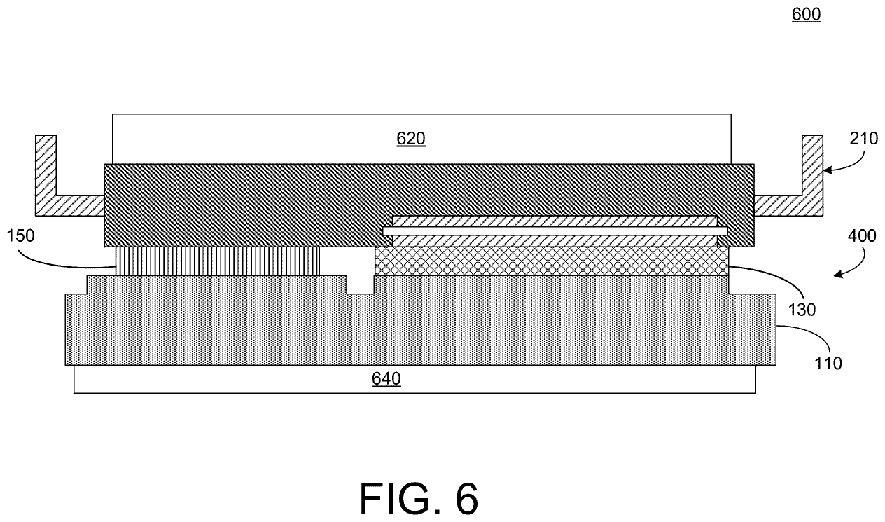

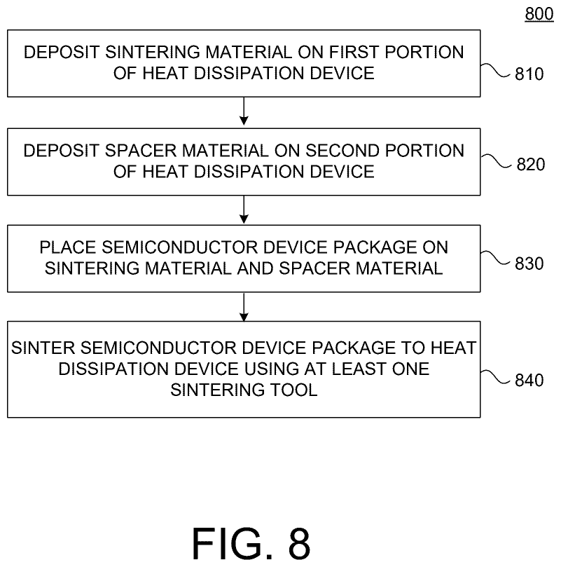

FIG. 1B is a diagram illustrating the example cooling jacket (the heat dissipation device 110) of FIG. 1A with spacer material 150 disposed on upper surfaces of the raised portions 140 of the cooling jacket, e.g., in addition to the conductive adhesive 130 disposed on the upper surfaces of the raised portions 120. As compared to the example of the FIG. 1A, in FIG. 1B the spacer material 150 is disposed on the respective upper surfaces of the raised portions 140. As shown in the FIG. 1B, the spacer material 150 is printed as a plurality of stripes on each of the upper surfaces of the raised portions 140. In some implementations, the spacer material 150 can be an epoxy, a silicone adhesive, a conductive material, a non-conductive material, an organic material, a semiconductor material, a metal alloy, a metal foam, a phase change material, etc. In some implementations a phase change material can include a polymer material. In some implementations, the spacer material can be printed in other ways, such as a single layer of material rather than a plurality of stripes of the spacer material 150. In some implementations, the spacer material 150 can include a film or tape, such as a Teflon® film or a tape including a phase change material, where the spacer material 150 is of a same thickness as the conductive adhesive 130, which can reduce and/or prevent package tilt during attachment (e.g., sintering) of a semiconductor device package to the heat dissipation device 110. For instance, the heat dissipation device 110 illustrated in FIG. 1B can be used to produce the example assembly shown in FIG. 4 using the approach shown in FIG. 6, and/or in accordance with the method of FIG. 8.

FIG. 2 is a diagram illustrating an example semiconductor device assembly 200. In some implementations, the semiconductor device assembly 200 can include the heat dissipation device 110 as shown in FIG. 1A (without the spacer material 150), or the heat dissipation device 110 as shown in FIG. 1B (with the spacer material 150). As shown in FIG. 2, the semiconductor device assembly 200 includes a plurality of semiconductor device packages 210, which are coupled with the heat dissipation device 110. For instance, exposed metal layers of respective DBM substrates included in the plurality of semiconductor device packages 210 can be respectively attached (sintered) to the raised portions 120 of the heat dissipation device 110. In example implementations including the heat dissipation device 110 illustrated in FIG. 1A, the semiconductor device assembly 200 can correspond with the example of FIG. 3. In example implementations including the heat dissipation device 110 illustrated in FIG. 1B, the semiconductor device assembly 200 can correspond with the example of FIG. 4.

As shown in FIG. 2, the semiconductor device packages 210 can include, respectively, a plurality of signal terminals 215. The plurality of signal terminals 215 can be power terminals, input signal terminals, output signal terminals, and so forth. In some implementations, the plurality of signal terminals 215 can be included in a leadframe. In some implementations, a leadframe can include any type of conductive portion of a package (e.g., conductive portion, conductive terminal) that can provide an external connection point from a package. Accordingly, a leadframe can be referred to as a conductive portion of a package or assembly. In some implementations, one or more portions of a leadframe can be coupled to a pad (e.g., a bond pad) on at least a portion of a DBM substrate and/or a semiconductor die.

FIG. 3 is a diagram schematically illustrating a cross-sectional view of an example semiconductor device assembly 300. As discussed above, the semiconductor device assembly 300 can include the heat dissipation device 110 as illustrated in FIG. 1A. FIG. 3 illustrates a schematic view of a cross-section of the semiconductor device assembly 300 through the heat dissipation device 110 and one of the semiconductor device packages 210 along the section line CS-CS in FIG. 2. As shown in FIG. 3, the semiconductor device package 210 includes a DBM substrate 220 that is partially encapsulated in a molding compound 230 (encapsulation material). A first primary surface of the semiconductor device package 210 includes a portion 211 that is defined by the molding compound a portion 221 that is defined by a metal layer of the DBM substrate 220, e.g., a metal layer on the bottom side of the DBM substrate 220 in the view of FIG. 3. A second primary surface 212 of the semiconductor device package 210 can, as shown in FIG. 3, is defined by the molding compound 230. In some implementations, the molding compound 230 is a non-conducting material, such as an epoxy, which can be formed (applied, etc.) using a transfer molding process or a compression molding process. In some implementations, the molding compound 230 can include a separate plastic housing that is included in the semiconductor device assembly 200.

While not specifically shown in this schematic view, the semiconductor device package 210 can also include one or more semiconductor die that are disposed on another metal layer of the DBM substrate 220 and encapsulated within the molding compound, e.g., a metal layer on the upper side of the DBM substrate 220 in the view of FIG. 3. Such semiconductor die can be electrically coupled with each other and/or with signal leads of the semiconductor device package 210 using conductive traces of the DBM substrate 220 and/or conductive elements, such as wire bonds, conductive clips, etc.

In some implementations, the semiconductor device packages 210 of the semiconductor device assembly 300 (or the semiconductor device assembly 400 illustrated in FIG. 4) can be implemented with hybrid die configurations. For instance, a semiconductor device package may include multiple semiconductor die of different types. For example, in a hybrid die configuration, the semiconductor device package may include a first semiconductor die that is implemented in silicon carbide (SiC) and a second semiconductor die that is implemented in silicon. Other combinations of die implemented in other semiconductor materials can also be used, e.g., in addition to, or in place of the examples above. In another example, a semiconductor device package can include a discrete semiconductor device, for example, a power transistor, a silicon carbide (SiC) MOSFET, or another device, and a fast-recovery diode implemented in silicon, or other semiconductor material.

As shown in FIG. 3, the portion 221 of the first primary surface of the semiconductor device package 210 defined by the metal layer of the DBM substrate 220 can be coupled (electrically and physically) with an upper surface 121 of the raised portion 120 via the conductive adhesive 130. In this example, an upper surface 141 of the raised portions 140 is spaced from the portion 221 of the first primary surface of the semiconductor device package 210 defined by the molding compound 230. In order to prevent tilting of the semiconductor device package 210 during attachment of the semiconductor device package 210 to the upper surface 121 of the raised portion 120, one or more position and level controllers can be used during a corresponding attachment process, e.g., a sintering process. For instance, the approach illustrated in FIG. 5 (and/or the method of FIG. 7) can be used to produce the semiconductor device assembly 300. While the examples described herein are generally described as using sintering for attaching an exposed metal layer of a semiconductor device package with a heat dissipation device, in some implementations, other approaches for attachment can be used, such solder reflow, conductive epoxy curing, etc.

In implementations using sintering to affect attachment of a semiconductor device package (e.g., the semiconductor device package 210) to a heat dissipation device (e.g., the heat dissipation device 110), the sintering operation can be a pressure-sintering operation. For instance, a pressure-sintering operation can include depositing a sintering material, such as by printing a sintering paste on a surface, such as the exposed metal layer of the semiconductor device package 210 or the upper surface 121 of the raised portion 120, and then placing a surface of another element on the sintering material. In this example, the other element can be the exposed metal layer of the semiconductor device package 210 or the upper surface 121 of the raised portion 120 to which sintering material was not applied.

The pressure-sintering operation can then include applying pressure to the semiconductor device package 210 and/or the heat dissipation device 110, e.g., with respective plates or other sintering tools. While applying pressure, the in-process assembly is heated to a sintering temperature to couple (sinter) the semiconductor device package 210 with the heat dissipation device 110. In some implementations, an inert gas flow (nitrogen) can be provided during the sintering process to prevent corrosion or oxidation of the surfaces being sintered, as well as the sintering material. In some implementations, after pressure-sintering is completed, the pressure plate and/or other tooling can be removed, and subsequent processing can be performed.

In some implementations, sintering can be or can include a process of fusing particles together into one solid mass by using, for example, a combination of pressure and/or heat without melting the materials. In some implementations, sintering can include making a material (e.g., a powdered material) coalesce into a solid or porous mass by heating it, and usually also compressing the material, without liquefaction. In some implementations, materials that can be used for sintering can include metals such as silver (Ag), copper (Cu) and/or metal alloys. In some implementations, sintered connections can have desirable electrical and/or thermal conductivity, durability, and a relatively high melting temperature.

In some implementations, soldering can be used to couple (e.g., electrically and/or physically couple) components of the semiconductor device assembly 200 with one another. For instance, soldering can include a process of joining two surfaces (e.g., metal surfaces) together using a molten filler metal (e.g., metal alloy, Tin (Sn), Lead (Pb), Silver (Ag), Copper (Cu)) that can be referred to as a solder. In some implementations, other approaches can be used for coupling metal surfaces of the semiconductor device assembly 200, such as welding, diffusion bonding, or conductive adhesives.

FIG. 4 is a diagram schematically illustrating a cross-sectional view of an example semiconductor device assembly 400. As discussed above, the semiconductor device assembly 400 can include the heat dissipation device 110 as illustrated in FIG. 1B. The example semiconductor device assembly 400 of FIG. 4 illustrates a schematic view of a cross-section through the heat dissipation device 110 and one of the semiconductor device packages 210 along the section line CS-CS in FIG. 2. As the semiconductor device assembly 400 includes similar aspects as the semiconductor device assembly 300 illustrated in FIG. 3, for purposes of brevity, those details will not be described again in detail here. Briefly, however, the semiconductor device assembly 400 can, for example, be produced using pressure-sintering (e.g., to couple a metal layer of a DBM substrate of the semiconductor device package 210 with the upper surface 121 of the raised portion 120), and can include semiconductor device packages 210 having hybrid die implementations. Depending on the particular implementations, the semiconductor device assembly 400 can include features and aspects that are the same as, or different than the semiconductor device assembly 300.

As shown in FIG. 4, the semiconductor device assembly 400 differs from the semiconductor device assembly 300 in that the spacer material 150 is disposed between the portion 211 of the primary surface of the semiconductor device package 210. In this example, the conductive adhesive 130 and the spacer material 150 can have a thickness T1 (a same thickness). In some implementations, the thickness T1 can be on the order of 100 micrometers (μm). As compared to approaches for producing the semiconductor device assembly 300 using one or more position and level controllers, in the example of FIG. 4, the spacer material 150 can prevent tilting of the semiconductor device package 210 during attachment of the semiconductor device package 210 to the upper surface 121 of the raised portion 120. For instance, the approach illustrated in FIG. 6 (and/or the method of FIG. 8) can be used to produce the semiconductor device assembly 400. Again, while the examples described herein are generally described as using sintering, e.g., pressure-sintering, for attaching an exposed metal layer of a semiconductor device package with a heat dissipation device, in some implementations, other approaches for attachment can be used, such solder reflow, conductive epoxy curing, etc.

In some implementations, the spacer material 150 can be a material that is mechanically held in place between the semiconductor device package 210 and the upper surface 141 of the raised portion 140. In some implementations, the spacer material 150 can be an adhesive material that, in combination with the conductive adhesive 130, couples the semiconductor device package 210 with the heat dissipation device 110. The spacer material 150 can include materials such as those described herein. The material or materials used for the spacer material 150 will depend on the particular implementation.

In some implementations, sintering can be or can include a process of fusing particles together into one solid mass by using, for example, a combination of pressure and/or heat without melting the materials. In some implementations, sintering can include making a material (e.g., a powdered material) coalesce into a solid or porous mass by heating it, and usually also compressing the material, without liquefaction. In some implementations, materials that can be used for sintering can include metals such as silver (Ag), copper (Cu) and/or metal alloys. In some implementations, sintered connections can have desirable electrical and/or thermal conductivity, durability, and a relatively high melting temperature.

In some implementations, the DBM substrate can include an insulating layer disposed between a first metal layer and a second metal layer. The insulating layer can be, for example, a ceramic layer. In some implementations, the insulating layer can be or can include, for example, a ceramic material such as alumina (Al₂O₃) or aluminum nitride (AlN)).

In some implementations, the first metal layer and/or the second metal layer can be or can function as a heat sink. In some implementations, the first metal layer and/or the second metal layer can be coupled to a heat sink. In some implementations, at least one or more of the first metal layer or the second metal layer can be exposed through a molding material.

In some implementations, the first metal layer and/or the second metal layer can be or can include a patterned metal layer including one or more electrically conductive traces. In some implementations, the first metal layer and/or the second metal layer can be or can include a patterned layer configured to form one or more electrical circuits, one or more conductive blind and/or through vias, and/or so forth.

In some implementations, the DBM substrate can be, or can include, a direct bonded copper (DBC) substrate. In some implementations, such as in DBC substrate implementations, the first metal layer and/or the second metal layer is a copper layer.

In some implementations, a DBM substrate can be formed by bonding one or more of the metal layers to the insulating layer. In some implementations, one or more of the metal layers can be bonded to the insulating layer using, for example, a high-temperature process.

Although referred to, by way of example, as a leadframe in this detailed description, the leadframe can include any type of conductive portion of a package (e.g., conductive portion, conductive terminal) that can provide an external connection point from a package. Accordingly, the leadframe can be referred to as a conductive portion of the package.

FIG. 5 is a diagram schematically illustrating an example approach for coupling (e.g., sintering) a semiconductor device package with a heat dissipation device using position and leveling control apparatus. In some implementations, the example approach of FIG. 5 can be used to produce the semiconductor device assembly 300 of FIG. 3, e.g., in accordance with the method of FIG. 7. Accordingly, the example approach of FIG. 5 will be described with further reference to semiconductor device assembly 300. In some implementations, the approach of FIG. 5 can be used to produce semiconductor device assemblies having other configurations.

In the example of FIG. 5, the semiconductor device assembly 300 is inverted as compared to the arrangement shown in FIG. 3. That is, in implementations of the approach of FIG. 5, the heat dissipation device 110 may be positioned above the semiconductor device package 210 during a corresponding sintering operation.

As shown in FIG. 5, the heat dissipation device 110 can be positioned against a sintering tool 520 using a plurality of position and level controllers 510. In some implementations, the sintering tool 520 can have a fixed position. In this example, each of the plurality of position and level controllers 510 can include a motor 512, such as a servo motor or a stepper motor, which is configured to operate (rotate, manipulate, control, etc.) a force screw 514 to manipulate a support member 516. For instance, the motors 512 of the position and level controllers 510 can rotate their respective force screws 514 to raise and lower the lower support members 516. In some implementations, a feedback control system (not shown) can be used to control the motors 512 to rotate the force screw 514 to raise the support members 516 to position and level the heat dissipation device 110 against the sintering tool 520 as shown in FIG. 5.

In the example of FIG. 5, the illustrated approach also includes using a plurality of position and level controllers 530, which are used to position and level the semiconductor device package 210 relative to the heat dissipation device 110, e.g., such that the exposed surface of the metal layer of the DBM substrate 220 contacts the conductive adhesive 130, and such that package tilt is prevented, or significantly reduced as compared to prior approaches. In this example, each of the position and level controllers 530 includes a motor 532 that is configured to operate a force screw 534 to raise and lower a support member 536. As shown in FIG. 5, the support members 536 can position and level the semiconductor device package 210 using a sintering tool 540 (e.g., a movable sintering tool) that is disposed between the support members 536 and the second primary surface 212 of the semiconductor device package 210. Furthermore, the plurality of position and level controllers 530 can use the support members 536 to apply pressure to the semiconductor device package 210, e.g., during a pressure-sintering operation.

As with the position and level controllers 510, the motors 532 of the plurality of position and level controllers 530 can be controlled (operated) using a feedback control system, which provides for accurate positioning and leveling of the semiconductor device package 210 relative to the heat dissipation device 110, as well as controlling an amount of pressure applied to the semiconductor device package 210. In this example, the sintering tool 520 and/or the sintering tool 540 can apply heat to the semiconductor device assembly 300 to facilitate attachment (e.g., sintering) of the semiconductor device package 210 to the heat dissipation device 110. Additionally, in some implementations, the sintering tool 520 and/or the sintering tool 540 can be configured to control an inert gas flow (e.g., nitrogen) during a sintering operation, e.g., to prevent corrosion and/or oxidation from occurring.

The number of plurality of position and level controllers 510 and plurality of position and level controllers 530 used in such an approach will depend on the particular implementation. For instance, using the approach of FIG. 5 to produce a semiconductor device assembly as illustrated by FIG. 2, the arrangement of FIG. 5 can used for each of the semiconductor device packages 210, e.g., could be implemented using six of the plurality of position and level controllers 510 and six of the plurality of position and level controllers 530. In implementations, different numbers of position and level controllers could be used. For instance, tooling could be used that allows for a single position and leveling controller to be used for positioning and leveling a heat dissipation device, and respective single position and leveling controllers used for positioning and leveling each semiconductor device package being coupled (sintered, etc.) to the heat dissipation device. Furthermore, the number of sintering tools used in such an approach can vary based on the particular implementation.

FIG. 6 is a diagram schematically illustrating an example approach for sintering a semiconductor device package with a heat dissipation device using a spacer material for leveling control. In some implementations, the approach shown in FIG. 6 can be used to produce the semiconductor device assembly 400 of FIG. 4. Accordingly, the example approach of FIG. 6 will be described with further reference to semiconductor device assembly 400. In some implementations, the approach of FIG. 6 can be used to produce semiconductor device assemblies having other configurations.

In the example of FIG. 6, the semiconductor device assembly 400 is in the same orientation as its arrangement shown in FIG. 4. That is, in implementations of the approach of FIG. 6, the heat dissipation device 110 may be positioned below the semiconductor device package 210 during a corresponding sintering operation.

In this example, the spacer material 150 can prevent or reduce package tilt by providing leveling control during an attachment (e.g., sintering) operation. As shown in FIG. 6, the heat dissipation device 110 is placed on a surface of a support member 640, which can be an assembly platform or table, In some implementations, the support member 640 can be a sintering tool. The semiconductor device package 210 is placed on the heat dissipation device 110, such that the metal layer of the first primary surface of the semiconductor device package 210 is placed on the conductive adhesive 130 and molding compound of the first primary surface of the semiconductor device package 210 is placed on the spacer material 150. A sintering tool 620 is then used to apply pressure to the semiconductor device package 210 on its second primary surface 212. In this approach, the conductive adhesive 130 and the spacer material 150 being of a same thickness provides leveling control of the semiconductor device package 210 relative to the heat dissipation device 110, e.g., prevents or reduces package tilt.

In this example, the sintering tool 620 and/or a sintering tool of the support member 640 can apply heat to the semiconductor device assembly 400 to facilitate attachment (e.g., sintering) of the semiconductor device package 210 to the heat dissipation device 110. In some implementations, the heat applied for sintering can also cause a phase change in the spacer material 150, e.g., from liquid to solid. Additionally, in some implementations, the sintering tool 620 and/or a sintering tool of the support member 640 can be configured to control an inert gas flow (e.g., nitrogen) during a sintering operation, e.g., to prevent corrosion and/or oxidation from occurring.

FIG. 7 is a flowchart illustrating an example method 700 for producing a semiconductor device assembly. In some implementations, the method 700 can be implemented using the approach of FIG. 5, e.g., to produce the semiconductor device assembly 300 of FIG. 3, or to produce semiconductor assemblies having other configurations. For purposes of illustration, the method 700 will be described with further reference to FIGS. 3 and 5.

At operation 710, the method 700 includes depositing a sintering material on a semiconductor device package. For example, a sintering material paste can be printed on the portion 221 of the first primary surface of the semiconductor device package 210 that is defined by the exposed metal layer of the DBM substrate 220. At operation 720, the method 700 includes placing the semiconductor device package 210 on the heat dissipation device 110, such as in the arrangement shown in FIG. 3 or FIG. 5. At operation 730, the method includes setting and leveling positions of the heat dissipation device 110 and the semiconductor device package 210 relative to each other and the sintering tools 520 and 540, such as in the arrangement shown in FIG. 5. That is, operation 730 can include positioning and leveling the heat dissipation device 110 against the sintering tool 520 using the position and level controllers 530. Operation 730 can further include positioning and leveling the semiconductor device package 210 and the sintering tool 540, e.g., in the arrangement shown in FIG. 5, and applying pressure to the semiconductor device package 210 using the position and level controllers 530. At operation 740, the method 700 includes performing a pressure sintering operation to couple the semiconductor device package 210 with the heat dissipation device 110 via the conductive adhesive 130, which can include applying heat and/or controlling an inert gas flow with corresponding sintering tools.

FIG. 8 is a flowchart illustrating an example method 800 for producing a semiconductor device assembly, which can be implemented using the approach of FIG. 6. In some implementations, the method 800 can be implemented using the approach of FIG. 6, e.g., to produce the semiconductor device assembly 400 of FIG. 4, or to produce semiconductor assemblies having other configurations. For purposes of illustration, the method 800 will be described with further reference to FIGS. 4 and 6.

At operation 810, the method 800 includes depositing sintering material on a first portion of a heat dissipation device, such as the raised portions 120 of the heat dissipation device 110. For example, a sintering material paste can be printed on the raised portions 120. At operation 820, the method 800 includes depositing the spacer material 150 on a second portion of a heat dissipation device, such as the raised portions 140 of the heat dissipation device 110. For example, a spacer material paste can be printed on the raised portions 140, or a film, tape or other material can be applied as the spacer material 150 on the raised portions 140. At operation 830, the method 800 includes placing the semiconductor device package 210 on the heat dissipation device 110, such as in the arrangement shown in FIG. 4 and FIG. 6. At operation 840, the method 800 includes performing a pressure sintering operation to couple the semiconductor device package 210 with the heat dissipation device 110 via the conductive adhesive 130, which can include applying heat and/or controlling an inert gas flow with one or more sintering tools. In the method 800, the spacer material 150, in combination with the conductive adhesive 130, provides leveling control to prevent or reduce package tilt.

In a general aspect, a semiconductor device assembly includes a heat dissipation device, and a semiconductor device package having a primary surface defined by an encapsulant material and a metal layer exposed through the encapsulant material. The assembly further includes a conductive adhesive coupling the metal layer of the primary surface with a first portion of the heat dissipation device. The assembly also includes a spacer material disposed between the encapsulant material of the primary surface and a second portion of the heat dissipation device.

Implementations can include one or more of the following features or aspects, alone or in combination. For example, the conductive adhesive can include a sintering material.

The spacer material can include at least one of a film, an epoxy, a tape, a silicone adhesive, or a phase change material. The spacer material can include a Teflon® film.

The first portion of the heat dissipation device can be a first raised portion having a first upper surface. The second portion of the heat dissipation device can be a second raised portion having a second upper surface that is coplanar with the first upper surface and discontinuous with the first upper surface.

The metal layer of the primary surface can be a metal layer of a direct-bonded metal substrate included in the semiconductor device package.

The heat dissipation device can be one of a cooling jacket, or a heatsink.

In another general aspect, a method for producing a semiconductor device assembly includes depositing a sintering material on a first portion of a heat dissipation device, and depositing a spacer material on a second portion of the heat dissipation device. The method also includes placing a first surface of a semiconductor device package on the sintering material and the spacer material such that a metal layer of the first surface is disposed on the sintering material and an encapsulation material of the first surface is disposed on the spacer material. The method further includes applying pressure to a second surface of the semiconductor device package with a sintering tool, where the second surface is opposite the first surface. The method further includes applying heat to the semiconductor device assembly to sinter the metal layer to the heat dissipation device with the sintering material.

Implementations can include one or more of the following features or aspects, alone or in combination. For example, depositing the sintering material on the heat dissipation device can include depositing the sintering material on an upper surface of a first raised portion of the heat dissipation device Depositing the spacer material on the heat dissipation device can include depositing the spacer material on an upper surface of a second raised portion of the heat dissipation device, the upper surface of the second raised portion being coplanar with the upper surface of the second raised portion.

Depositing the sintering material on the heat dissipation device can include printing a sintering material paste on the first portion of the heat dissipation device.

Depositing the spacer material on the heat dissipation device can include printing a spacer material paste on the second portion of the heat dissipation device. The spacer material paste can be one of an epoxy, a silicone adhesive, or a phase change material.

The method can include providing an inert gas flow to the semiconductor device assembly while applying heat.

While applying pressure and applying heat, the semiconductor device package can be positioned above the heat dissipation device.

In another general aspect, a method for producing a semiconductor device assembly includes depositing a sintering material on a metal layer included in a first surface of a semiconductor device package, and placing the semiconductor device package on a heat dissipation device such that the sintering material is in contact with a first surface of the heat dissipation device. The method further includes positioning a second surface of the heat dissipation device in contact with a first sintering tool using a first motor-operated level controller, where the second surface of the heat dissipation device is opposite the first surface of the heat dissipation device. The method also includes applying pressure to a second surface of the semiconductor device package with a second sintering tool using a second motor-operated level controller. The second surface of the semiconductor device package is opposite the first surface of the semiconductor device package. The method also includes applying heat to the semiconductor device assembly to sinter the metal layer to the heat dissipation device with the sintering material.

Implementations can include one or more of the following features or aspects, alone or in combination. For example, the first surface of the heat dissipation device can be an upper surface of a raised portion of the heat dissipation device.

Depositing the sintering material on the metal layer can include printing a sintering material paste on the metal layer.

The method can include providing an inert gas flow to the semiconductor device assembly while applying heat.

While applying pressure and applying heat, the heat dissipation device can be positioned above the semiconductor device package.

In another general aspect, an apparatus for producing a semiconductor device assembly includes: a first sintering tool that has a fixed position. The apparatus also includes a first motor-operated level controller configured to position a heat dissipation device in contact with the first sintering tool. The apparatus further includes a second sintering tool, and a second motor-operated level controller configured to apply pressure to a semiconductor device package with the second sintering tool during a sintering operation to sinter the semiconductor device package to the heat dissipation device.

Implementations can include one or more of the following features or aspects, alone or in combination. For example, the first sintering tool and the second sintering tool can be configured to apply heat to the semiconductor device assembly for the sintering operation, and control an inert gas flow during the sintering operation.

The first motor-operated level controller can include a force screw, and one of a servo motor or a stepper motor for rotating the force screw to position the heat dissipation device in contact with the first sintering tool.

The second motor-operated level controller can include a force screw, and one of a servo motor or a stepper motor for rotating the force screw to apply pressure to the semiconductor device package with the second sintering tool.

It will be understood that, in the foregoing description, when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, top, bottom, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Silicon Carbide (SiC), Gallium Arsenide (GaAs), Gallium Nitride (GaN), and/or so forth.

While certain features of the implementations described have been illustrated as described herein, many modifications, substitutions, changes and equivalents will now occur to those skilled in the art. For instance, features illustrated and/or aspects described with respect to one implementation can, where appropriate, also be included in, and/or apply to other implementations. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A semiconductor device assembly comprising:
a heat dissipation device;
a semiconductor device package having a primary surface defined by an encapsulant material and a metal layer exposed through the encapsulant material;
a conductive adhesive coupling the metal layer of the primary surface with a first portion of the heat dissipation device; and
a spacer material disposed between the encapsulant material of the primary surface and a second portion of the heat dissipation device.

2. The semiconductor device assembly of claim 1, wherein the conductive adhesive includes a sintering material.

3. The semiconductor device assembly of claim 1, wherein:
the first portion of the heat dissipation device is a first raised portion having a first upper surface; and
the second portion of the heat dissipation device is a second raised portion having a second upper surface that is coplanar with the first upper surface and discontinuous with the first upper surface.

4. The semiconductor device assembly of claim 1, wherein the metal layer of the primary surface is a metal layer of a direct-bonded metal substrate included in the semiconductor device package.

5. The semiconductor device assembly of claim 1, wherein the heat dissipation device is one of:
a cooling jacket; or
a heatsink.

6. The semiconductor device assembly of claim 1, wherein the spacer material includes at least one of:
a film;
an epoxy;
a tape;
a silicone adhesive; or
a phase change material.

7. The semiconductor device assembly of claim 1, wherein the spacer material includes a Teflon® film.

8. A method for producing a semiconductor device assembly, the method comprising:
depositing a sintering material on a first portion of a heat dissipation device;
depositing a spacer material on a second portion of the heat dissipation device;
placing a first surface of a semiconductor device package on the sintering material and the spacer material such that:
a metal layer of the first surface is disposed on the sintering material; and
an encapsulation material of the first surface is disposed on the spacer material;
applying pressure to a second surface of the semiconductor device package with a sintering tool, the second surface being opposite the first surface; and
applying heat to the semiconductor device assembly to sinter the metal layer to the heat dissipation device with the sintering material.

9. The method of claim 8, wherein:
depositing the sintering material on the heat dissipation device includes depositing the sintering material on an upper surface of a first raised portion of the heat dissipation device; and
depositing the spacer material on the heat dissipation device includes depositing the spacer material on an upper surface of a second raised portion of the heat dissipation device, the upper surface of the second raised portion being coplanar with the upper surface of the second raised portion.

10. The method of claim 8, wherein depositing the sintering material on the heat dissipation device includes printing a sintering material paste on the first portion of the heat dissipation device.

11. The method of claim 8, wherein depositing the spacer material on the heat dissipation device includes printing a spacer material paste on the second portion of the heat dissipation device.

12. The method of claim 11, wherein the spacer material paste is one of:
an epoxy;
a silicone adhesive; or
a phase change material.

13. The method of claim 8, further comprising:
providing an inert gas flow to the semiconductor device assembly while applying heat.

14. The method of claim 8, wherein, while applying pressure and applying heat, the semiconductor device package is positioned above the heat dissipation device.

15. A method for producing a semiconductor device assembly, the method comprising:
depositing a sintering material on a metal layer included in a first surface of a semiconductor device package;
placing the semiconductor device package on a heat dissipation device such that the sintering material is in contact with a first surface of the heat dissipation device;
positioning a second surface of the heat dissipation device in contact with a first sintering tool using a first motor-operated level controller, the second surface of the heat dissipation device being opposite the first surface of the heat dissipation device;
applying pressure to a second surface of the semiconductor device package with a second sintering tool using a second motor-operated level controller, the second surface of the semiconductor device package being opposite the first surface of the semiconductor device package; and
applying heat to the semiconductor device assembly to sinter the metal layer to the heat dissipation device with the sintering material.

16. The method of claim 15, wherein the first surface of the heat dissipation device is an upper surface of a raised portion of the heat dissipation device.

17. The method of claim 15, wherein depositing the sintering material on the metal layer includes printing a sintering material paste on the metal layer.

18. The method of claim 15, further comprising:
providing an inert gas flow to the semiconductor device assembly while applying heat.

19. The method of claim 15, wherein, while applying pressure and applying heat, the heat dissipation device is positioned above the semiconductor device package.

20. An apparatus for producing a semiconductor device assembly, the apparatus comprising:
a first sintering tool, the first sintering tool having a fixed position;
a first motor-operated level controller configured to position a heat dissipation device in contact with the first sintering tool;
a second sintering tool; and
a second motor-operated level controller configured to apply pressure to a semiconductor device package with the second sintering tool during a sintering operation to sinter the semiconductor device package to the heat dissipation device.

21. The apparatus of claim 20, wherein the first sintering tool and the second sintering tool are configured to:
apply heat to the semiconductor device assembly for the sintering operation; and
control an inert gas flow during the sintering operation.

22. The apparatus of claim 20, wherein the first motor-operated level controller includes:
a force screw; and
one of a servo motor or a stepper motor for rotating the force screw to position the heat dissipation device in contact with the first sintering tool.

23. The apparatus of claim 20, wherein the second motor-operated level controller includes:
a force screw; and
one of a servo motor or a stepper motor for rotating the force screw to apply pressure to the semiconductor device package with the second sintering tool.
